(19) United States
(12) Patent Application Publication
(10) Pub. No.: US 2024/0015913 A1
(43) Pub. Date: Jan. 11, 2024

(54) Electronic Device, Drying Assembly and Method

(71) Applicant: Eberspächer catem GmbH & Co. KG, Herxheim (DE)

(72) Inventors: Ralf Lothar Weinand, Worth am Rhein (DE); Kai-Fabian Bürkle, Hinterweidenthal (DE); Simon Georg Kräck, Karlsruhe (DE)

(21) Appl. No.: 18/219,410

(22) Filed: Jul. 7, 2023

(30) Foreign Application Priority Data
Jul. 11, 2022 (DE) 10 2022 117 225.2

(51) Int. Cl. H05K 5/06; H05B 1/02; B01D 53/26; B01D 53/04

(52) U.S. Cl. CPC H05K 5/069; H05B 1/0236; B01D 53/261; B01D 53/0438; B01D 53/0454; H05B 2203/02; B01D 2257/80; B01D 2253/104; B01D 2259/40098; B01D 2259/4566

(57) ABSTRACT

A control device in a vehicle has an electronic housing in which control components are accommodated, and a drying assembly having a dryer housing in which a hygroscopic drying agent is accommodated and which has at least one opening communicating with the electronic housing. The drying assembly is adapted such that the opening prevents the passage of the drying agent into the electronic housing.

### BACKGROUND OF THE INVENTION

### 1. Field of the Invention

The present invention relates to an electronic device. This device may be any electronic device, in particular control device or electronics in a terminal. In particular, the present invention relates to an electronic device in a vehicle, preferably in a motor vehicle.

### 2. Background of the Invention

In electronic devices, there is the problem that moisture in the air can lead to electrical malfunction of the contained control components inside the devices. The control components are, for example, printed circuit boards or circuit boards, in particular equipped with electronic components such as chips, power transistors, capacitors, switching elements and the like. However, control components can also be simple electrical conductors. In sufficiently humid environments, and especially in high-voltage applications above e.g. 50 V, such control components are exposed to the risk of damage to the control components caused by the moisture, leading for example to failure of the control components. This is due to the fact that with increasing moisture of air, the dielectric strength decreases. In addition, leakage currents can also flow across surfaces as long as a certain moisture prevails. Especially in the context of electromobility, which uses a plurality of control components in vehicles, it is therefore particularly important to keep moisture away from the control components. Moisture can be in the form of condensation water, i.e. water condensed out due to temperature changes in the air, or in the form of humid air. Moisture can also be present simply as water that has penetrated.

In this context, the present invention is particularly aimed at increasing the electrical safety of an electronic device which is used under varying climatic conditions or, at least temporarily, in high humidity and which is used, in particular, in controlling or regulating high-voltage current. High-voltage current is preferably considered to be an electric current at a voltage of at least 50 V. Such high-voltage currents are controlled in particular in the field of electromobility and especially in control devices for electric heating devices in a motor vehicle. Thus, the electronic device according to the invention is preferably used as a control device for an electric heating device in a vehicle on water, on land and in the air, preferably in a motor vehicle.

The control or regulation of such high-voltage currents requires an increased dielectric strength of the components used for this purpose or of the surrounding gas or the surrounding air. Special requirements are placed on air and leakage paths. The configuration case assumes low moisture and thus low electrical conductivity of the air and the component surfaces due to moisture in the electronic housing. In practical operation, however, this assumption cannot always be met.

### SUMMARY

The underlying problem of the present invention is to provide an electronic device, a drying assembly for an electronic device and a method by way of which an increased electrical safety of the electronic device is enabled.

For the solution, an electronic device, in particular control device in a vehicle, is provided with an electronic housing in which control components are accommodated, and a drying assembly with a dryer housing in which a hygroscopic drying agent is accommodated and which has at least one opening communicating with the electronic housing. The drying assembly is adapted such that the opening prevents the passage of the drying agent into the electronic housing. Thus, the opening may be sufficiently small relative to the drying agent, comprise a barrier or membrane, and/or be aligned so that the drying agent cannot pass through the opening. The drying assembly can be accommodated in the electronic housing and/or attached to the electronic housing, typically such that the opening can communicate with the electronic housing, in particular wherein the opening is fluidically connected to the electronic housing for this purpose.

The electronic device may in principle be configured to be self-dehumidifying. In this way, the risk of electronic malfunction is minimized. In the process, the drying assembly in particular takes up only a small amount of space from the electronic device itself. The drying assembly can in fact be dimensioned in different ways and is thus highly adaptable. The drying assembly can be attached to the electronic housing from the inside and/or from the outside, whereby it is protected and easily replaceable. In particular, because the drying assembly does not have to be configured completely integrally with the electronic housing, it can be used flexibly. The invention avoids condensation water or humid air collecting in the electronic housing. This increases the safety of the electronic device.

Depending on the temperature and humidity, the drying agent can dehumidify or regenerate autonomously, thus without any active intervention. During regeneration, the moisture absorbed by the drying agent is released back into the environment. In particular, the drying agent can regenerate when the temperature and/or humidity tend to rise and/or fall. Therefore, in typical use where temperature and humidity fluctuate, the drying agent may not only automatically absorb moisture, but also automatically release it. For example, when the electronic device is operated in a dry and/or warm environment, the drying agent can release moisture. The release of moisture can then be unproblematic in the area of the electronic housing because the ambient air can at least temporarily absorb this moisture in such an environment. The drying agent can advantageously act as a kind of buffer for the moisture, which means that replacement of the drying agent and/or regeneration with the use of a separate regeneration device can be dispensed with.

Silicate or silica gel can be provided as the drying agent. Silicate is inexpensive. Silicate can be used at temperatures up to 80° C. or 90° C., for example, to bind moisture or water. At even higher temperatures, for example at 100° C., regeneration of the silicate can take place (at the so-called regeneration temperature), wherein the silicate then cannot bind moisture or water.

Activated aluminum oxide and/or molecular sieve can be provided as the drying agent. These drying agents have a higher regeneration temperature compared to silicate, e.g. 200° C. This increases the application temperature for absorbing moisture, e.g. to 160° C. or 180° C.

For example, the drying agent can absorb 20-30% of its own weight in moisture.

Mixtures of different drying agents, for example a mixture of aluminum oxide and molecular sieve, can also be provided. This can provide cost advantages. In addition, technical properties of different drying agents can thus be combined.

The electronic device may be installed in an electric vehicle. There, electrical currents are usually controlled or regulated at over 200 volts. This is done in the mostly closed electronic housings, which accommodate strip conductors and/or power transistors as control components, for example, in order to control or regulate the electrical currents. Not least because of the increased safety requirements to be met in the operation of a motor vehicle, moisture in the electronic housings must therefore be avoided, which can be enabled by using the invention in this area. However, the electronic device can also be used in other areas, such as in buildings, in order to increase operational safety there as well.

Other mobile areas are also possible, e.g. in airplanes or other aircraft such as helicopters. This is possible because the electronic device, especially the drying assembly, can be lightweight.

In particular, the device according to the invention can dehumidify itself autonomously. It is therefore also conceivable to use the device in cases where air conditioning of an electronic device via an air cycle in the electronic housing is not technically feasible in order to keep moisture out. This may be the case, for example, on ships, in airplanes, in helicopters or even in buildings.

The opening can be provided with a membrane. For example, a membrane that is permeable to water vapor and impermeable to water can be used. Humid air can then pass through the membrane to the drying agent and be dehumidified.

For continuous air exchange with the electronic housing and/or for pressure equalization, the dryer housing can have a further opening. The further opening on the dryer housing can be at least substantially opposite the opening, is arranged spaced apart from the opening, and/or is arranged on another section of the dryer housing. For example, one opening can be arranged in the electronic housing and the other opening can be arranged outside the electronic housing so that the air exchange from outside the electronic housing is always dried. In this respect, the further opening can have a valve or non-return valve that may allow only one air passage in the direction through the dryer housing in order to dehumidify only the air entering the electronic housing. In addition, the electronic housing can be provided with pressure equalization with the environment via the opening and the further opening in the dryer housing. By this solution, it can also be dispensed with that the electronic housing has or must have another means for pressure equalization. Such another means can be a membrane, which is arranged e.g. independently of drying agents at the electronic housing.

A retainer, typically a grid or screen, may be provided in the dryer housing. The drying agent can be fixed or retained in the dryer housing by way of the retainer. The retainer can separate the dryer housing, in particular as a kind of leaking wall, to create an area free of drying agent. However, the retainer may also already serve to prevent the drying agent from passing through or exiting the opening. The retainer ensures that the drying agent is not moved around randomly in the dryer housing, which can in fact destroy or crush the drying agent by friction. The retainer acts as a kind of coarse filter for the air moving through the opening.

The dryer housing may be detachably connected to the electronic housing, because this allows easy replacement despite the dryer housing being securely held in or on the electronic housing.

The dryer housing can also be configured to be openable, for example in that the membrane can be removed from the opening, that an openable closure is provided on the dryer housing, and/or that the dryer housing can be unscrewed. In this way, the drying agent can be easily checked and/or replaced.

In particular, the dryer housing is configured to be at least substantially or at least sectionally rigid. This provides further protection for the drying agent contained therein. This also ensures good attachability of the dryer housing or drying assembly, e.g. to or in the electronic housing. However, this also ensures an improved process of moisture absorption by the drying agent, because there can be less indeterminate deformation from the dryer housing and the communication, in particular of air via the opening, is simplified or rarely obstructed. In this context, a rigid or the rigid section of the dryer housing can be provided with a fastener for detachable connection to the electronic housing. However, the fastener or a further fastener can also be provided away from the dryer housing, for example on or in the electronic housing, and be configured correspondingly to the dryer housing or to the fastener of the dryer housing. The fastener may comprise a clip connection, a screw connection, a clamp connection or the like. In this respect, the rigid section or the rigid dryer housing also enables a simplified connection or fastening, in particular detachable fastening.

The fastener may be provided on the dryer housing between the opening and the further opening so that the drying assembly can be used on the electronic housing to equalize the pressure.

The fastener may have a tapered thread that is provided for sealing. The fastener may also be provided with a sealing means such as a sealing ring in order to seal. In particular, when the dryer housing is attached to the electronic housing, a tight connection must be created to allow air exchange from the dryer housing into the electronic housing, possibly only via the opening.

If a regeneration device is provided for regenerating the drying agent, the autonomy of the electronic device with regard to dehumidification can be increased. The drying agent or the drying assembly can thus be used approximately permanently and/or without regular maintenance replacement. This is because the regeneration or regenerating by the regeneration device enables that drying agent saturated with moisture can be transferred back to a state in which it contains less moisture in order to be able to absorb moisture again. In particular, the regeneration device is arranged on the dryer housing or integrated therein. For example, the regeneration device can be electrically controlled so that the moisture contained in the drying agent is released back out of the opening by heat generated from the electrical energy, namely when it is required and/or when it seems just appropriate (for example, when the electronic housing is open and/or when there is a high ambient temperature and/or low humidity). The regeneration device may also initiate a chemical process in conjunction with the drying agent to allow the drying agent to absorb further moisture.

In a further configuration of the regeneration device, it is provided that the regeneration device comprises at least one PTC heating element that is thermally coupled to the drying agent. “Thermally” means, for example, a possibility of heat transfer by conduction, convection and/or radiation. The regeneration device can thus ensure dehumidification of the drying agent via a PTC heating element by allowing the drying agent to be heated. In this context, the PTC heating element may be comparatively small in its dimensions, because it is only a matter of heating the drying agent. For example, power classes of PTC heating elements for the regeneration device in the range of up to 10 W, 100 W or 1 kW are provided here, while the electronic device per se is intended indirectly or directly for motor units which are dimensioned at least one order of magnitude, possibly at least two or three orders of magnitude, larger with respect to the power class, for example above 100 W, 1 kW, 10 kW, 100 kW, or more than 1 MW.

The regeneration device may be accommodated in the dryer housing to protect the regeneration device and to provide a space-saving, simplified, and technically low-fault structure of the drying assembly in the electronic device.

Likewise in the aforementioned context, the dryer housing can be configured in two parts and/or have or configure an accommodation chamber for the drying agent and an accommodation chamber for the regeneration device. In particular, the accommodation chambers are separated from each other, for example fluidically and/or spatially separated. The accommodation chambers can be thermally coupled via a partition wall. The partition wall can then dissipate heat released by the regeneration device, for example by means of heat conduction and/or heat radiation, to the adjacent accommodation chamber containing the drying agent. An electrical connection for the PTC heating element and/or a further opening, in particular with a membrane, can be provided on the outside of the connection chamber for the regeneration device. In particular, the regeneration device can be well protected in this way and can only be used as required.

In a further embodiment, a PTC heating element electrically connected to the electronic device, which can be controlled by at least one of the control components and is configured to heat a heat carrier, is provided. In particular, this PTC heating element is to be considered independent of the regeneration device. In this respect, it is proposed that the electronic device according to the invention is used specifically in connection with electronic heating devices for or with PTC heating elements. For example, the electronic device can safely control PTC heating elements because the electronic housing is always well dehumidified. This increases operational reliability.

The drying assembly and/or the regeneration device can, for example, have an indicator, in particular sensor and/or reactive mechanism in the drying agent, which can, for example, index or measure the temperature, humidity and/or moisture or saturation from the drying agent. The indicator may also index based on time interval or cycle. In particular, the indicator is used to determine, indicate and/or report when or if regeneration is necessary. The indicator can indicate such a need, request and/or initiate regeneration indirectly or directly. For example, when it is detected that the drying agent is no longer capable of absorbing sufficient moisture, the indicator may issue a message. Alternatively or additionally, the indicator can issue a message at a fixed time interval. In response to the message, the regeneration device can carry out regeneration or a replacement of the drying assembly can be carried out. A reactive mechanism in the drying agent may indicate saturation, for example, by discoloration.

The drying assembly can also be replaced regularly in the sense of a preventive measure, in particular independently of the actual saturation. This can be indicated or requested by the indicator. The initially mentioned problem is also solved by a drying assembly for an electronic device, in particular for a control device in a vehicle, wherein the electronic device has an electronic housing with control components accommodated therein, wherein the drying assembly comprises a rigid dryer housing in which a hygroscopic drying agent is accommodated and which comprises at least one opening communicating with the electronic housing, wherein the drying assembly is adapted such that the opening prevents the passage of the drying agent into the electronic housing. The drying assembly may comprise a regeneration device for regenerating the drying agent and/or a fastener for detachable connection to an electronic housing. In other words, a drying assembly is proposed that is specifically adapted to an electronic device. In particular, this drying assembly is well suited for retrofitting to existing electronic devices to reduce the risk of damage caused by moisture. The drying assembly can prevent or at least substantially reduce condensation water in electronic housings. The features and advantages described above apply accordingly to this drying assembly.

Finally, the initially mentioned problem is also solved by a method for operating an electronic device, in particular a control device in a vehicle, in which a hygroscopic drying agent exposed to the atmosphere inside the electronic device is regenerated, in particular cyclically, by means of a regeneration device. The method can take place inside and also outside the electronic device. For example, the method can be performed by the operator of the electronic device or by a third party who is not the operator of the electronic device. In particular, the indicator described above is used in the method because, for example, this provides an opportunity to use the regeneration device at the most sensible times. Overall, the method provides flexibility in the use of electronic devices or drying assemblies.

In the method, the drying agent may be temporarily heated, in particular to an average temperature of 100° C.+/−10° C., in particular 200+/−20° C., or more, for example for several seconds, minutes or hours. The average temperature may correspond to the regeneration temperature of the drying agent. The drying assembly or the drying agent can be weighed, e.g. before and/or after heating, to determine the saturation of the drying agent. In the method, the used drying agent can also be removed and a dry or unsaturated drying agent can be introduced into the drying assembly.

The regeneration device can be ready for operation, operated and/or temporarily deactivated depending on the ambient temperature, humidity and/or the operation of at least one of the control components. The regeneration device can thus be actuated or controlled in a manner adapted to the environment. This is because the bound moisture is released from the drying agent during regeneration. This may only take place when the environment is rather warm and dry, especially when the environment has already been rather warm and dry for a certain period of time, e.g. several minutes or hours. In this way, the moisture escaping from the drying agent can be prevented from settling or having a detrimental effect on the electronic housing.

For example, the regeneration device may be operational or operated during high outside temperatures, e.g., in summer, and/or deactivated for the duration of low outside temperatures, e.g., in winter. The regeneration device may be deactivated when at least one of the control components responsible for a PTC heating element is operated. The regeneration device may also be deactivated during high humidity, rain and/or thunderstorms.

In particular, data recorded by sensors, e.g. from a temperature sensor, can be used to decide on the operation or deactivation of the regeneration device. For example, vehicle data, software executed on a control component and/or a control component with a switching logic can be used for controlling the regeneration device adapted to the environment.

If regeneration can only be done at rather low humidity (e.g., below 90%, 75%, or 50% relative humidity) and/or with the PTC heating element not operated by the control components, the moisture from the drying agent is typically released without any risk.

The drying assembly, in particular the dryer housing, can have at least one, in particular temperature-sensitive, valve, in particular with a thermostat and/or a bimetal. The valve can open or also close during operation of the regeneration device, due to heat and/or by a command. The valve can open or also close when the regeneration device is switched off. The valve can be provided to open or close the opening and/or the further opening of the dryer housing. The valve can also be electrically controllable to open or close via a command. This may allow that moisture from the drying agent is selectively dissipated into the dryer housing and/or into the environment.

The preferred features and advantages described above apply accordingly to the method.

In the context of the disclosure described above and below, the term “or” stands as a short form for “or rather” and is basically intended to indicate alternative, basically equivalent and/or synonymous features or terms in order to convey the idea or meaning of a feature or term usage in more detail. “Or” can always be replaced with “and/or”.

### BRIEF DESCRIPTION OF THE DRAWINGS

Further details and advantages of the present invention will be apparent from the following description of an embodiment in conjunction with the drawing. Therein:

FIG. 1 shows an electronic device comprising a drying assembly, which is arranged in a vehicle, in a schematic side view,

FIG. 2 shows a further electronic device with a drying assembly comprising a regeneration device in a schematic side view,

FIG. 3 shows a further electronic device, in which a drying assembly is placed, in a schematic side view,

FIG. 4 shows an electronic device comprising a drying assembly electrically connected to a PTC heating element for heating a heat carrier in a perspective schematic view, and

FIG. 5 shows a method for regenerating a drying agent by way of a regeneration device in a schematic view.

### DETAILED DESCRIPTION

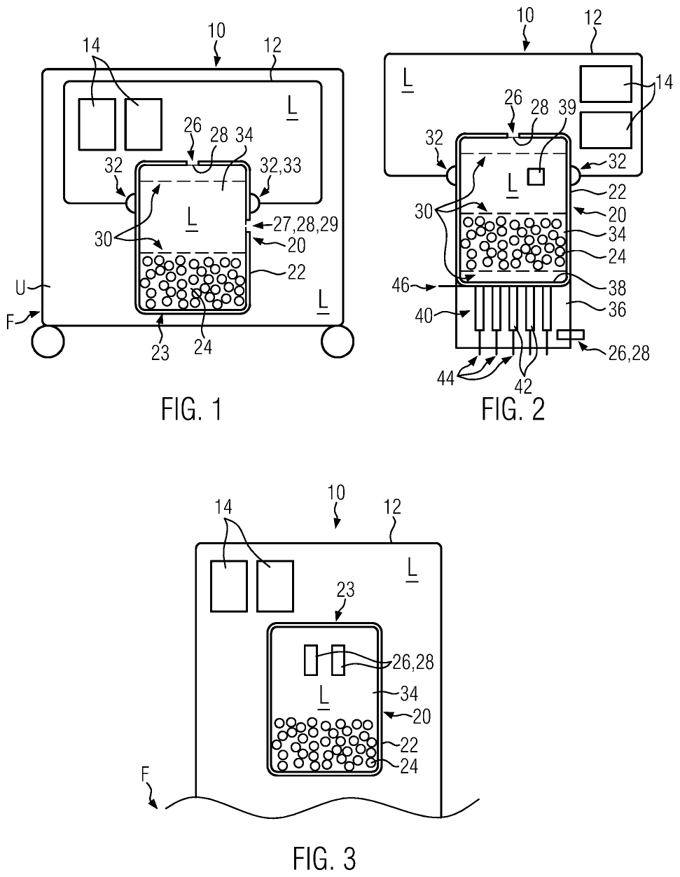

FIG. 1 shows a first embodiment of an electronic device 10. This is a control device in a vehicle F containing the device 10 and shown abstractly framing the device 10. The control components 14 accommodated in an electronic housing 12 are configured, for example, for controlling a drive motor of the vehicle F, which is configured as an electric vehicle. Moreover, the electronic housing 12 has air L which may contain moisture. The device 10 comprises a drying assembly 20.

In a rigid dryer housing 22 of the drying assembly 20 containing air L, more specifically in an accommodation chamber 34 of the dryer housing 22, a hygroscopic drying agent 24 containing activated aluminum oxide is accommodated. The dryer housing 22 includes an opening 26 communicating with the electronic housing 12. The drying assembly 20 is adapted such that the opening 26 prevents the drying agent 24 from passing into the electronic housing 12 because the opening 26 is sufficiently small relative to the drying agent 24, and because the opening 26 is provided with a membrane 28 that is impermeable to water and permeable to water vapor.

A retainer 30 formed as a grid is arranged in the dryer housing 22. The grid fixes the drying agent 24 in the dryer housing 22 in the lower area. In the upper area, another retainer 30 is provided to further prevent the passage of the drying agent 24 into the electronic housing 12.

The dryer housing 22 is detachably connected to the electronic housing 12 by means of a fastener 32 configured in particular as a cylindrical external thread, in that it is screwed there into a fastener 32 configured as a threaded bore. Via the connection at the fastener 32, the opening 26 is directed into the electronic housing 12, so that here the drying agent can enter into fluid communication with the volume or the air L therein.

In particular, the fastener 32 seals within itself or the fastener 32 seal against each other. This is because the fastener 32 of the dryer housing 22 has a sealing means 33 configured as a sealing ring, which circumferentially abuts and seals the electronic housing 12. Alternatively, the thread can be configured conically to achieve a seal by compression.

The dryer housing 22 includes another opening 27 which is in communication with the environment U of the electronic housing 12 and can accommodate, dehumidify and deliver air L therethrough to the electronic housing 12. The further opening 27 is provided with a further membrane 28 and a one-way valve 29, in particular to prevent water from entering the dryer housing 22 from the vehicle and to prevent air from escaping away from the electronic housing 12. The valve 29 is also temperature-sensitive or has a thermostat and opens above a predetermined or predeterminable temperature.

The further opening 27 is opposite, or more precisely diagonally opposite, the opening 26. The fastener 32 is arranged between the further opening 27 and the opening 26. The further opening 27 thus enables pressure equalization of the electronic housing 12.

The dryer housing 22 is further provided with a lock 23 in the form of a screw cap, by means of which the dryer housing 22 is configured to be openable. The dryer housing 22 can be unscrewed thanks to the lock 23, for example in order to replace the drying agent 24.

FIG. 2 shows a second embodiment of an electronic device 10. This device 10, too, can be used in the same way as the device 10 of FIG. 1 of a vehicle F, which is however hidden in the present case. The device 10 is a control device with an electronic housing 12, in which two control components 14 are accommodated, and which otherwise has air L or humid air L. A drying assembly 20 having a dryer housing 22 containing air L is in fluid communication with the electronic housing 12 or with the air L therein via an opening 26 provided with a membrane 28. The drying assembly 20 is screwed to the electronic housing 12 via fastener 32, wherein an external thread on the dryer housing 22 is configured conically and therefore seals in a clamping manner in the cylindrical internal thread of the electronic housing 12, in particular wherein Teflon tape is applied to the external thread here to improve the sealing. The drying assembly 20 can thus keep the electronic housing 12 free of atmospheric moisture or water vapor.

The dryer housing 22 is configured in two parts and has two accommodation chambers 34, 36 which are separated from one another by a partition wall 38. In this regard, the partition wall 38 causes the accommodation chambers 34, 36 to be thermally coupled. For example, the partition wall 38 can transmit or conduct a heat flow between the accommodation chambers 34.

In an accommodation chamber 34, which is the upper accommodation chamber 34 in FIG. 2, a drying agent 24 is accommodated, wherein the drying agent 24 is fixed between two retainers s 30 configured as a grid. Another retainer 30 is arranged near the opening 26. The opening 26 prevents the drying agent 24 from passing into the electronic housing 12 because it is smaller than the drying agent 24 and due to the membrane 28.

In the dryer housing 22, there is further arranged an indicator 39 that can be used to determine the saturation of the drying agent 24. The indicator 39 may also determine a humidity and/or temperature within the dryer housing 22.

In the other accommodation chamber 36, a regeneration device 40 is accommodated for regeneration, i.e. treatment or dehumidification, of the drying agent 24, which in the present case has five PTC heating elements 42. The mass of the PTC heating elements 42, for example, is accessible via electrical poles 44 projecting from the end face of the dryer housing 22. At the height of the partition wall 38, an electrical pole 46 is accessible, for example a positive pole of all PTC heating elements 42.

Likewise at the other accommodation chamber 36, an opening 26 provided with a membrane 28 is arranged in the present case in order to keep moisture also out of this accommodation chamber 36. This is because, during operation of the PTC heating elements 42, heat in the accommodation chamber 36 will thus ensure dehumidification of this accommodation chamber 36 and ultimately the escape of moisture from the opening 26.

To the extent that the regeneration device 40 is operated, thus basically operating the PTC heating elements 42, this leads to heating of the entire dryer housing 22 or both accommodation chambers 34, 36. The partition wall 38 thereby acts as a kind of hearth plate. By heating the accommodation chamber 34 and the drying agent 24 contained therein, the drying agent 24 is regenerated and can absorb new moisture. By heating, the moisture from the drying agent 24 is released into water vapor or air L and in turn can escape from the accommodation chamber 34 through the opening 26.

In FIG. 2, the regeneration device 40 is not electrically connected, in particular not electrically connected to one of the control components 14. The reason for this is that the regeneration device 40 is not to be operated in the installed state on the electronic housing 12 or on the control components 14. In particular, the drying assembly 20 is to be released or the detachable connection is to be released and then, outside of the electronic housing or outside of a vehicle F, the regeneration device 40 is to be electrically connected and operated so that the drying agent 24 is regenerated.

However, it is also possible that the regeneration device 40 is operated in the installed state, in particular in a vehicle F; in this case, the regeneration device 40 can be electrically connected to a control component 14, wherein one of the control components 14 is then connected indirectly or directly to the poles 44, 46, and the regeneration device 40 can be controlled by the control component 14 and operated, for example, by means of a method, in particular cyclically.

FIG. 3 primarily shows an embodiment of the invention in which a drying assembly 20 is completely inserted in an electronic housing 12 of an electronic device 10. The electronic housing 12 has, in addition to air L, in the present case two control components 14 which serve to control on-board electronics in a vehicle F.

The drying assembly 20 is configured for the electronic device 10 and comprises a rigid dryer housing 22 with a single accommodation chamber 34. A hygroscopic drying agent 24 made of silicate is accommodated in the accommodation chamber 34. The dryer housing 22 has two openings 26 communicating with the electronic housing 12. The drying assembly 20 is adapted such that the openings 26 prevent the drying agent 24 from passing into the electronic housing. Namely, the openings 26 are each provided with a membrane 28. The drying assembly 20 shown and preferred in this respect does not have a regeneration device 40 and can be easily retrofitted in an existing electrical device 10, in particular which does not comprise a drying assembly 20. Likewise, this drying assembly 20 can be easily replaced.

The drying assembly 20 may have a lock 23 clipped to the dryer housing 22, in particular, to allow the dryer housing 22 to be opened, as is also the case in FIG. 3.

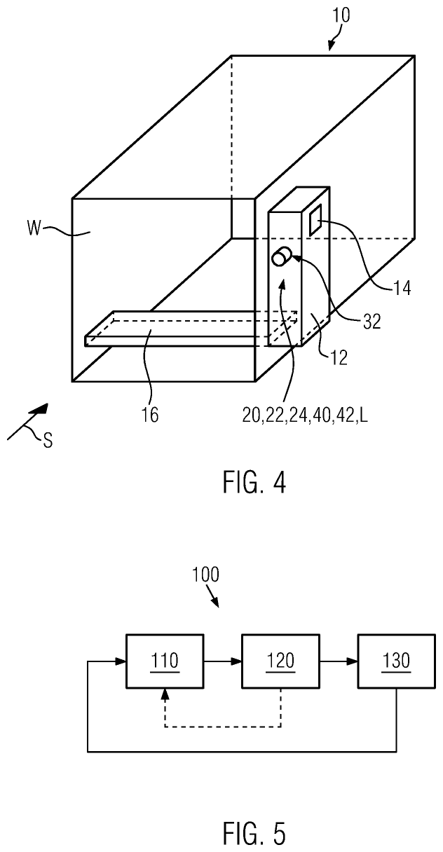

FIG. 4 shows a further embodiment in which an electronic device 10 is configured to heat a heat carrier W, for example air L, flowing through the device 10 in a flow direction S via a PTC heating element 42. Namely, control components 14 in an electronic housing 12 are configured to control or operate the PTC heating element 42 oriented transversely to the flow direction S. In this respect, the electronic device 10 is also configured as that of FIG. 2, thus, it comprises a drying assembly 20 with a dryer housing 22 with a drying agent 24 contained therein and, furthermore, a regeneration device 40 with a PTC heating element 42. Likewise, air L is present in the electronic housing 12 or in the dryer housing 22. The drying assembly 20 is screwed to the electronic housing 12 via fastener 32.

FIG. 5 shows a method 100 according to the invention for operating an electronic device 10, in which a hygroscopic drying agent 24 exposed to the atmosphere inside the electronic device 10 is cyclically regenerated by means of a regeneration device 40. The method 100 may be carried out in or on the electronic housing 12 of the device 10 or outside thereof, for example at a service provider substantially concerned with the function from the drying agent 24 or with the function of drying assemblies 20. Two preferred variations of the method 100 are described below.

Preferably, the method 100 of FIG. 5 proceeds as follows. In a first step 110, a saturation of the drying agent 24 is detected by means of an indicator 39, whereupon it is proceeded to the next step 120. In the subsequent step 120, the saturation is compared to a threshold value. If the saturation is lower than the threshold value, a fixed time interval is waited, for example one hour, and the step 110 or method 100 is restarted by continuing to follow the dashed line. When the saturation is higher than the threshold, a third step 130 is initiated. In the third step 130, the regeneration device 40 is operated for a fixed time interval, for example several minutes, wherein a heat is released that heats the drying agent 24 so that the saturation of the drying agent 24 decreases as the moisture evaporates from the drying agent 24. Preferably, an average temperature of the drying agent 24 of 200° C.+/−20° C. is reached in the fixed time interval. Subsequently, step 110 can be started again. This method leads to a cyclic regeneration, for example about every hour, which however is also only initiated when the regeneration is appropriate with respect to the saturation of the drying agent 24.

The method 100 of FIG. 5 may also proceed as follows. In a first step 110, a fixed time interval is waited for, for example one hour, wherein after the time interval has elapsed, step 120 is carried out. In step 120, the regeneration device 40 is operated for a fixed time interval, for example several minutes, wherein heat is released that heats the drying agent 24 so that the saturation of the drying agent decreases as the moisture evaporates from the drying agent 24. Preferably, an average temperature of the drying agent 24 of 200° C.+/−20° C. is reached in the fixed time interval. In the subsequent step 130, which is started after completion of step 120, the fixed time interval, for example the one hour, is then restarted and it is immediately returned to step 110, where the time interval is then waited for again. This method results in cyclic regeneration, for example every hour, which occurs regardless of the saturation of the drying agent 24.

1. An electronic device, comprising:
an electronic housing in which control components are accommodated; and
a drying assembly having a dryer housing in which a hygroscopic drying agent is accommodated and which has at least one opening communicating with the electronic housing, wherein the drying assembly is adapted such that the opening prevents the passage of the drying agent into the electronic housing.

2. The electronic device according to claim 1, further comprising a grid or screen that is provided in the dryer housing, and wherein the drying agent is fixed or retained in the dryer housing via the grid or the screen.

3. The electronic device according to claim, wherein the dryer housing is detachably connected to the electronic housing.

4. The electronic device according to claim 1, wherein the dryer housing is configured to be at least substantially or sectionally rigid, wherein the rigid section of the dryer housing is provided with a fastener that releasably connects the dryer housing to the electronic housing.

5. The electronic device according to claim 1, further comprising a regeneration device that is configured to regenerate the drying agent.

6. The electronic device according to claim 5, wherein the regeneration device comprises at least one PTC heating element which is convectively and/or radiantly coupled to the drying agent.

7. The electronic device according to claim 5, wherein the regeneration device is accommodated in the dryer housing.

8. The electronic device according to claim 5, wherein the dryer housing is configured in at least two parts and forms an accommodation chamber for the drying agent and a separate accommodation chamber for the regeneration device.

9. The electronic device according to claim 1, further comprising a PTC heating element which is electrically connected to the electronic device, which can be controlled by at least one of the control components, and which is configured for heating a heat carrier.

10. The electronic device according to claim 1, wherein the electronic device is configured to be installed in a vehicle.

11. A drying assembly for a control device in a vehicle, wherein the control device comprises an electronic housing with control components accommodated therein, the drying assembly comprising: a rigid dryer housing in which a hygroscopic drying agent is accommodated and which comprises at least one opening communicating with the electronic housing, wherein the drying assembly is adapted such that the opening prevents passage of the drying agent into the electronic housing.

12. The drying assembly according to claim 11, wherein the dryer housing has a further opening formed therein.

13. The drying assembly according to claim 11, wherein the drying assembly comprises a regeneration device for regenerating the drying agent and/or a fastener for releasable connecting the drying assembly to an electronic housing

14. A method for operating a control device in a vehicle, comprising:
cyclically recycling, via a regeneration device, a hygroscopic drying agent exposed to the atmosphere inside the electronic device.
